(19) United States
(12) Patent Application Publication
(10) Pub. No.: US 2005/0253269 A1
(43) Pub. Date: Nov. 17, 2005

(54) Semiconductor device

(75) Inventor: Hiroshi Tsuda, Kanagawa (JP)

Correspondence Address: YOUNG & THOMPSON, Suite 200, 745 23rd Street, Arlington, VA, 22202, US

(73) Assignee: Semiconductor Leading Edge Technologies, Inc., Tsukuba-shi (JP)

(21) Appl. No.: 11/015,016

(22) Filed: Dec. 20, 2004

(30) Foreign Application Priority Data
May 12, 2004 (JP) 2004-141835

(51) Int. Cl. H01L 27/14

(52) U.S. Cl. 257/758

(57) ABSTRACT

A semiconductor device comprises a semiconductor layer; a stacked body; and an electrode pad provided on the stacked body. The stacked body is provided on the semiconductor layer and has a plurality of stacked layers. The electrode pad is provided on the stacked body. The stacked body has a subpad region that is located below the electrode pad and an extrapad region that is not located below the electrode pad, and any portion made of insulating material in the electrode subpad region except a contact plug layer directly above the semiconductor layer in the stacked body is surrounded by a metal interconnect having a closed structure in the same layer.

### CROSS-REFERENCE TO ERLATED APPLICATIONS

This application is based upon and claims the benefit of priority from the prior Japanese Patent Application No. 2004-141835, filed on May 12, 2004; the entire contents of which are incorporated herein by reference.

### BACKGROUND OF THE INVENTION

The invention relates to a semiconductor device, and more particularly, to a semiconductor device resistant to occurrence of failure even if it is made of less strong insulating material having less compact film structure or insulating material prone to peeling off when stacked.

In recent years, in order to address requests for downscaling and speed enhancement of semiconductor devices, not only the scaling of transistors fabricated in the semiconductor substrate surface but also the scaling of interconnect layer portions connecting between the transistors have been indispensable. When an interconnect layer portion is scaled down, the product RC of the resistance R of the interconnect portion and the insulating film capacitance C between the interconnects serves as a time constant to govern the interconnect delay. For this reason, interconnect layer portions are multilayered. In addition, for interconnect material, rather than conventionally used material mainly composed of aluminum (Al), material mainly composed of copper (Cu) having lower resistance has been required. For insulating film material, it has become necessary to use material having lower dielectric constant than conventionally used silicon oxide film or FSG (fluorinated silicate glass).

Here, the insulating film material having lower dielectric constant includes CVD (chemical vapor deposition) film made of silicon oxide film doped with organic groups, coating material containing organic ingredients, and material made of the CVD film or coating film containing pores. However, these insulating films have low mechanical strength and hardness. A problem is that in a probe test for operation check before shipment, the film itself is peeled off or broken by mechanical impact transmitted from the probe needle. Another problem is that the film itself is peeled off or broken by impact due to vibration and load applied during bonding wires for retrieving electrical signals from or supplying power to the semiconductor chip.

In this respect, for enhancing strength below pad electrodes, a method is proposed that embeds metal film partially below the pad (Japanese Laid-Open Patent Applications 2.001-308100 and 2001-267323).

FIG. 12 is a cross-sectional view showing a structure investigated by the inventor based on this method.

In a front end layer 1201, diffusion layers, gate electrodes, and transistors are formed as appropriate on a semiconductor substrate. The front end layer 1201 is covered, across a contact plug layer 1202, sequentially with interconnect layers 1204, 1205, 1206, and 1207 including interconnects 1203 provided for connection in the same layer. On top, adhesion/barrier metal, pad connecting Al 1208, and a passivation layer 1209 are placed. Via layers 1210, 1211, and 1212 are provided above and below the interconnect layers to connect between different interconnect layers. Vias 1213 are formed to electrically connect the interconnects. For material of insulating films 1214 and 1215 above the interconnect layer 1204, low-k film having a relative dielectric constant of 3 or less can be used. The interconnects and vias can be made of metal mainly composed of copper.

FIG. 13 is a perspective plan view showing the interconnect layers 1204 and 1205 and the via layer 1210 superimposed from the upper surface in the pad portion 1216 of this semiconductor device.

According to a common design standard, as shown in FIG. 13, a metal portion 1301 in the interconnect layer is made of combination of wide interconnects. A metal portion 1302 in the via layer increases strength below the pad by being packed with strut-like vias.

Other structures for improving mechanical strength of the portion below, the electrode pad include the following.

FIG. 14 is a cross-sectional view showing another specific example structure for improving mechanical strength of the portion below the electrode pad. In this specific example, metal film 1401 is embedded entirely below the electrode pad portion 1216.

FIG. 15 is a cross-sectional view showing yet another specific example structure for improving mechanical strength of the portion below the electrode pad. In this specific example, the underlying conducting layer is directly bonded.

Application of these structures can enhance durability of electrode portions against impact during bonding and adhesion between layers.

On the other hand, as described above, the insulating film material having lower dielectric constant includes CVD film made of silicon oxide film doped with organic groups, coating material containing organic ingredients, and material made of the CVD film or coating film containing pores. Such insulating film material is less compact in film structure. For this reason, in the process after the semiconductor substrate is diced into chips, insulating material may allow moisture or corrosive gas to intrude from the exposed side surface of the chip, which leads to the cause of disconnection failure by corroding metal interconnects serving as signal lines or power supply lines in the semiconductor chip.

In this respect, a structure is proposed for preventing intrusion of moisture and corrosive gas in the process after the semiconductor substrate is diced into chips (Japanese Laid-Open Patent Applications 2000-269219 and 2003-86590).

FIG. 16 is a perspective plan view showing this structure. More specifically, pad portions 1602 are provided surrounding the inside 1601 of the semiconductor chip. A metal interconnect 1603 surrounds the chip along its periphery.

However, after independent investigation, the inventor has found that there still remain problems that cannot be avoided by the structures described above. More specifically, while it is naturally expected that both of the two problems described above, that is, the problem of peeling off and breakdown of film below pad electrodes and the problem of intruding moisture or corrosive gas after dicing into chips, can be solved by simultaneous implementation of all the ideas described above. However, the inventor has found that there occur problems that cannot be avoided by implementing a simple collection of such ideas.

For example, when the structure of embedding metal film partially below the pad (see the first and second patent documents) is used, metal portions below the pad are typically dot-shaped, as shown in FIG. 13, in the layer corresponding to the via layer provided for electrically connecting between different interconnect layers. As a result, when a characteristic test is performed by probing the interconnect structure in the course of fabricating it into the semiconductor substrate, the probe needle (now shown) may penetrate the top interconnect layer as shown in FIG. 17. In this case, the crack 1701 may reach low-k insulating film 1215 in the via layer. This results in a problem of intrusion of moisture or corrosive gas, which leads to the cause of disconnection failure by corroding metal interconnects serving as signal lines or power supply lines in the semiconductor chip. Furthermore, also during wire bonding, there is a risk that a crack 1701 may be produced in the top interconnect layer to expose insulating material directly below the interconnect layer. This results in a problem of causing similar failure.

On the other hand, as illustrated in FIG. 14, when the structure of embedding metal film entirely (see the first and second patent documents) is used, the fabrication process is complicated if the metal film is embedded later in the pad portion. Even if a method of embedding metal film upon fabrication of each layer is used, the metal interconnect spread entirely across a wide area of the pad portion incurs a greater amount of polishing when CMP (Chemical Mechanical Polishing) is used. This causes a problem of “dishing”, that is, reduced thickness of the metal interconnect below the pad. In fact, large unevenness occurs in the same layer, which causes the risk of peeling off or defocusing in the exposure process, thus making it difficult to fabricate a desired semiconductor device.

In addition, as illustrated in FIG. 15, the method of directly bonding the underlying conducting layer (see the first and second patent documents) involves a complicated fabrication process and increases the area occupied by the pad portion. Therefore this method is disadvantageous for downscaling of semiconductor chips.

As described above, when less strong insulating material having less compact film structure or insulating material prone to peeling off when stacked is used and a characteristic test is performed by probing the interconnect structure in the course of fabricating it into the semiconductor substrate or bonding to the pad is performed, it is a challenging problem to avoid exposure of the insulating material having less compact film structure. In particular, it is very difficult to fabricate devices, which must meet future demands for further downscaling, without using complicated processes.

### SUMMARY OF THE INVENTION

According to an aspect of the invention, there is provided a semiconductor device comprising: a semiconductor layer; a stacked body provided on the semiconductor layer and having a plurality of stacked layers; and an electrode pad provided on the stacked body, wherein the stacked body has a subpad region that is located below the electrode pad and an extrapad region that is not located below the electrode pad, and any portion made of insulating material in the electrode subpad region except a contact plug layer directly above the semiconductor layer in the stacked body is surrounded by a metal interconnect having a closed structure in the same layer.

Each of the plurality of layers may include a pad periphery metal interconnect surrounding the periphery of the subpad region.

A portion in which the pad periphery metal interconnects provided in respective adjacent layers overlap with each other may have a closed structure surrounding the subpad region.

At least one of the plurality of layers may have a plurality of the pad periphery metal interconnects spaced apart by insulating material and formed circularly.

The plurality of layers have an interconnect layer may provide with an interconnect for electrical connection inside the same layer and a via layer may provide with an interconnect for electrical connection between different layers,
the interconnect layer may have the pad periphery metal interconnect with a large width, and the via layer may have a plurality of the pad periphery metal interconnects with a small width.

The plurality of layers may have an interconnect layer provided with an interconnect for electrical connection inside the same layer and a via layer provided with an interconnect for electrical connection between different layers, the metal interconnect of the via layer in the subpad region may have a smaller planar area than the metal interconnect of the interconnect layer in the subpad region.

At least one of the plurality of layers may have insulating material with lower mechanical strength or hardness than silicon oxide film or FSG (fluorinated silicate glass) as the insulating material.

At least one of the plurality of layers may have insulating material having a relative dielectric constant of 3 or less as the insulating material.

Each of the plurality of layers except the contact plug layer directly above the semiconductor layer may have the chip periphery metal interconnect provided in the extrapad region surrounding the vicinity of the periphery of the chip.

The plurality of layers may have an interconnect layer provided with an interconnect for electrical connection inside the same layer and a via layer provided with an interconnect for electrical connection between different layers, the interconnect layer may have the chip periphery metal interconnect with a large width, and the via layer may have the chip periphery metal interconnect with a small width.

At least one of the plurality of layers may have a plurality of the chip periphery metal interconnects spaced apart by insulating material and formed circularly.

According to another aspect of the invention, there is provided a semiconductor device comprising: a semiconductor layer; a stacked body provided on the semiconductor layer and having a plurality of stacked layers; and a plurality of electrode pads provided on the stacked body, wherein the stacked body has a plurality of subpad regions that are located below the plurality of electrode pads, respectively, and an extrapad region that is not located below the electrode pads, and each of the plurality of layers includes a chip periphery metal interconnect surrounding all the plurality of subpad regions.

A portion in which the chip periphery metal interconnects provided in respective adjacent layers overlap with each other may have a closed structure surrounding the subpad regions.

At least one of the plurality of layers may have a plurality of the chip periphery metal interconnects spaced apart by insulating material and formed circularly.

The plurality of layers may have an interconnect layer provided with an interconnect for electrical connection inside the same layer and a via layer provided with an interconnect for electrical connection between different layers, the interconnect layer may have the chip periphery metal interconnect with a large width, and the via layer may have a plurality of the chip periphery metal interconnects with a small width.

The plurality of layers may have an interconnect layer provided with an interconnect for electrical connection inside the same layer and a via layer provided with an interconnect for electrical connection between different layers, and the metal interconnect of the via layer in the subpad region may have a smaller planar area than the metal interconnect of the interconnect layer in the subpad region.

At least one of the plurality of layers may have insulating material with lower mechanical strength or hardness than silicon oxide film or fluorinated silicate glass.

At least one of the plurality of layers may have insulating material having a relative dielectric constant of 3 or less.

Each of the plurality of layers may include a plurality of pad periphery metal interconnects surrounding the periphery of the plurality of subpad regions, respectively.

The plurality of layers may have an interconnect layer provided with an interconnect for electrical connection inside the same layer and a via layer provided with an interconnect for electrical connection between different layers, the interconnect layer may have the pad periphery metal interconnect with a large width, and the via layer may have the pad periphery metal interconnect with a small width.

According to the invention, a semiconductor device which is resistant to failure even when less strong insulating material having less compact film structure or insulating material prone to peeling off when stacked is used and a characteristic test is performed by probing the interconnect structure in the course of fabricating it into the semiconductor substrate or bonding to the pad is performed, and thus, the merit on industry is great.

### BRIEF DESCRIPTION OF THE DRAWINGS

The present invention will be understood more fully from the detailed description given herebelow and from the accompanying drawings of the embodiments of the invention. However, the drawings are not intended to imply limitation of the invention to a specific embodiment, but are for explanation and understanding only.

In the drawings:

FIG. 1 is a cross-sectional view showing a semiconductor device according to an embodiment of the invention;

FIG. 2 is a perspective plan view showing the interconnect layers 104 and 105 and the via layer 110 superimposed from the upper surface in the subpad region 116 of the semiconductor device shown in FIG. 1;

FIG. 3 is a plan view showing only the portion corresponding to the interconnect layers 104 and 105 extracted from FIG. 2.

FIG. 4 is a plan view showing only the via layer 110 extracted from FIG. 2;

FIG. 5 is a graphical diagram showing the result of measurements by the inventor;

FIG. 6 is a plan views showing variations of the first embodiment of the invention;

FIG. 7 is a plan view showing variations of the first embodiment of the invention;

FIG. 8 is a plan view showing variations of the first embodiment of the invention;

FIG. 9 is a plan view showing variations of the first embodiment of the invention;

FIG. 10 is a perspective plan view illustrating the planar structure of a relevant part of a semiconductor device according to a second embodiment of the invention;

FIG. 11 is a schematic view showing a cross-sectional structure of a chip periphery metal interconnect 1002;

FIG. 12 is a cross-sectional view showing a structure investigated by the inventor;

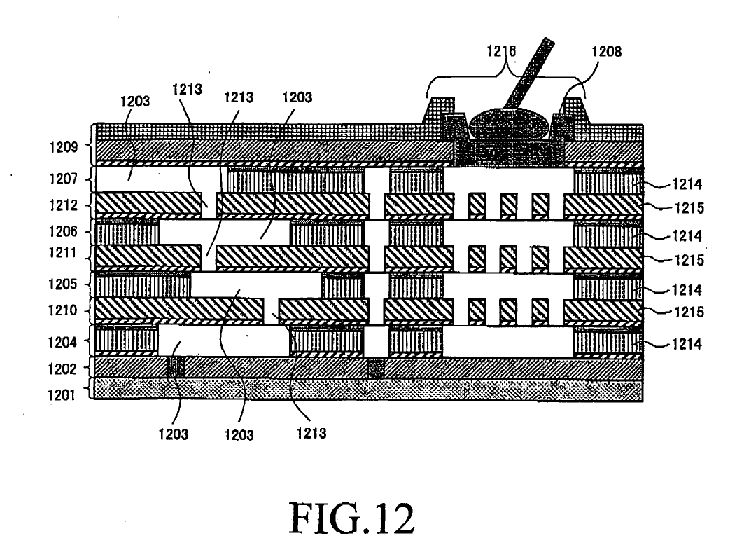

FIG. 13 is a perspective plan view showing the interconnect layers 1204 and 1205 and the via layer 1210 superimposed from the upper surface in the pad portion 1216 of the semiconductor device shown in FIG. 12;

FIG. 14 is a cross-sectional view showing another specific example structure for improving mechanical strength of the portion below the electrode pad;

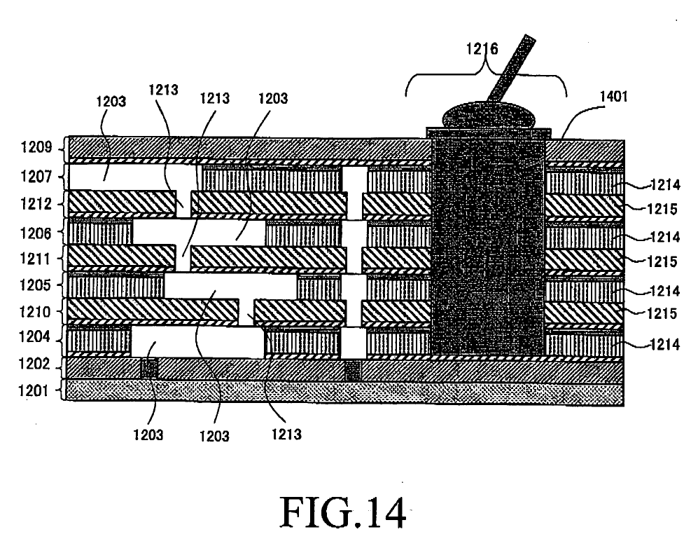

FIG. 15 is a cross-sectional view showing yet another specific example structure for improving mechanical strength of the portion below the electrode pad;

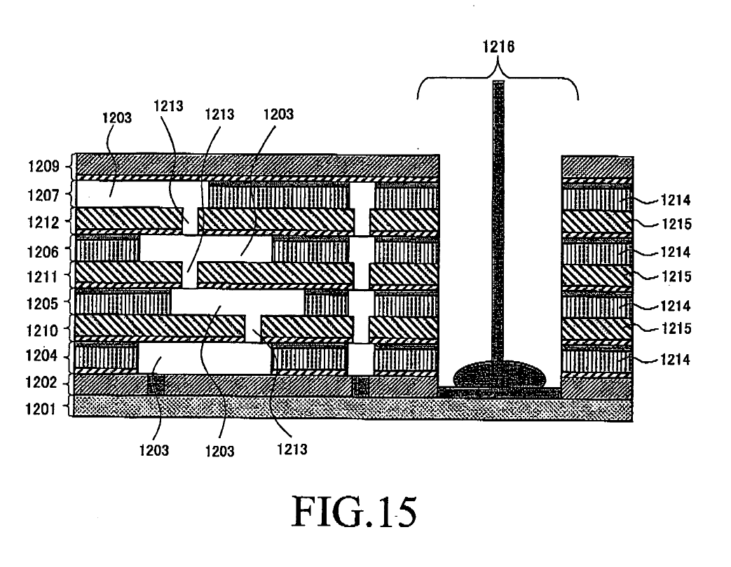

FIG. 16 is a perspective plan view showing the structure for preventing intrusion of moisture and corrosive gas in the process after the semiconductor substrate is diced into chips; and

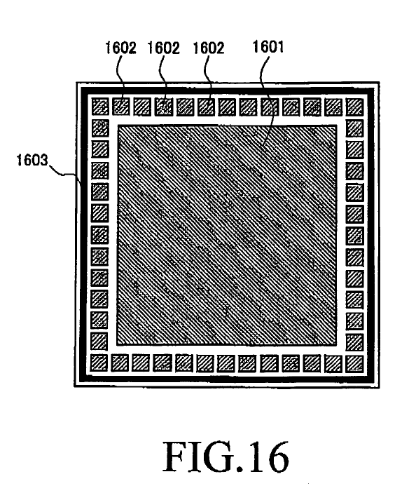

FIG. 17 is a schematic cross-sectional view illustrating the state in which a probe needle has penetrated the top interconnect layer.

### DETAILED DESCRIPTION

Embodiments of the invention will now be described in detail with reference to the drawings.

### First Embodiment

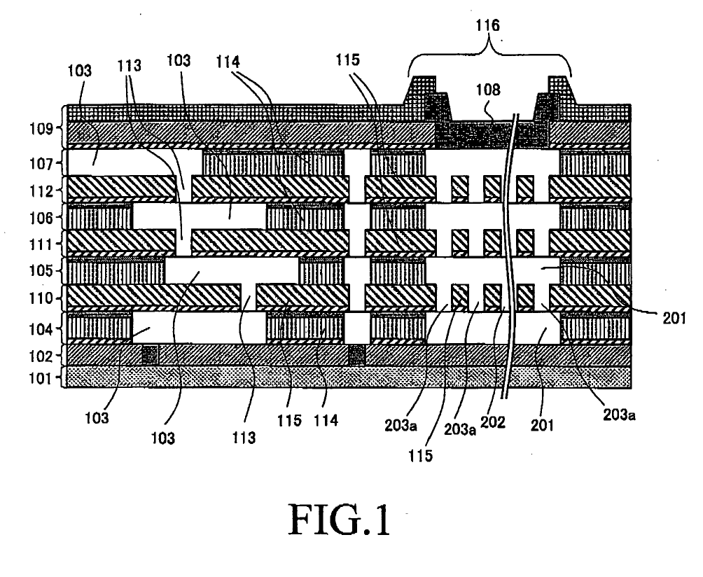

FIG. 1 is a cross-sectional view showing a semiconductor device according to an embodiment of the invention.

More specifically, the semiconductor device comprises a front end layer 101 in which diffusion layers, gate electrodes, and transistors are formed on a semiconductor substrate. The front end layer 101 is covered, across a contact plug layer 102, sequentially with interconnect layers 104, 105, 106, and 107 including interconnects 103 provided for connection in the same layer. On top, adhesion/barrier metal, pad connecting aluminum (Al) 108, and a passivation layer 109 are placed. The region below the pad connecting aluminum 108 will be referred to as “subpad region”, and the other region as “extrapad region”.

It should be noted that in an actual semiconductor device, a predetermined number of interconnect layers and via layers are repeatedly stacked to form a multilayer interconnect. However, it is omitted in FIG. 1 for simplicity.

In this semiconductor device, via layers 110, 111, and 112 are provided above and below the interconnect layers to connect between different interconnect layers. Vias 113 are formed to electrically connect the interconnects. Here, for material of insulating films 114 and 115 above the interconnect layer 104, it is desirable to use material having lower dielectric constant than silicon oxide film or FSG (fluorinated silicate glass). It is desirable to use low-k film having a relative dielectric constant of 3 or less. This can reduce the parasite capacitance between the interconnect layers, which leads to fast operation. The interconnects and vias can be made of metal mainly composed of copper (Cu). This can reduce the parasite resistance of the interconnect layers, which suppresses interconnect delay and leads to fast operation.

It should be noted that thin films made of different insulating materials may be provided as appropriate above and below these low-k films. For example, an insulating thin film mainly composed of silicon (Si) and carbon (C) is provided below the insulating film 114 provided in the interconnect layer 104. This thin film serves as an etching stopper film during dry etching. In addition, an insulating thin film mainly composed of silicon oxides is provided above the insulating film 114 provided in the interconnect-layer 104. This thin film serves to suppress damage imposed on the low-k film during the process.

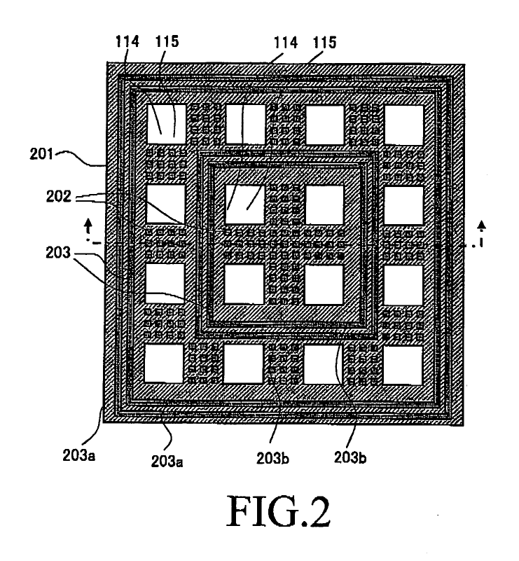

FIG. 2 is a perspective plan view showing the interconnect layers 104 and 105 and the via layer 110 superimposed from the upper surface in the subpad region 116 of this semiconductor device. It should be noted that in this figure, interconnects extending from the pad portion to the inside of the semiconductor chip are omitted.

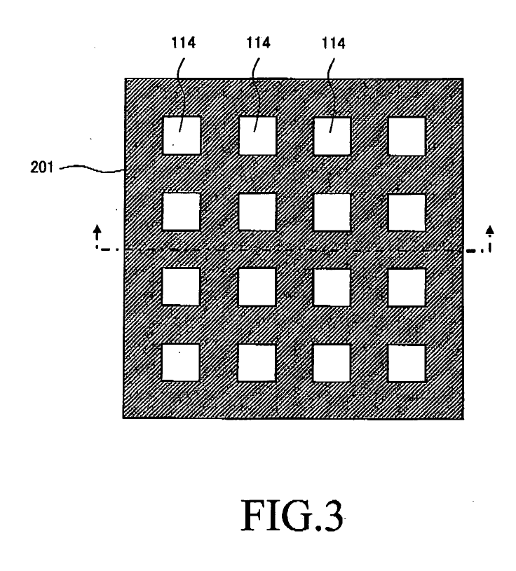

FIG. 3 is a plan view showing only the portion corresponding to the interconnect layers 104 and 105 extracted from FIG. 2. The cross-sectional structure along the dashed cutting line shown in these figures is shown in FIG. 1.

A metal portion 201 is configured like a lattice. In each interconnect layer, low-k insulating material 114 in the subpad region is surrounded by the metal portion.

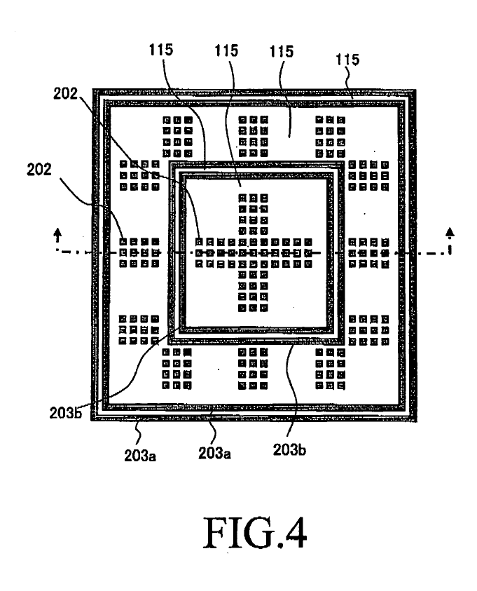

FIG. 4 is a plan view showing only the via layer 110 extracted from FIG. 2. The cross-sectional structure along the dashed cutting line shown in this figure is shown in FIG. 1.

Metal portions in the via layer 110 are marked with reference numerals 202 and 203. The metal portion 202 is an ordinary via, shaped like a strut in the via layer 110. On the other hand, the metal portion 203 forms a closed-loop interconnect, and has a structure that surrounds the low-k insulating material 115 located in the subpad region. In other words, as shown in FIGS. 2 to 4, the insulating materials 114 and 115 in each layer of the subpad region is arranged so that they are always surrounded by metal interconnects 201 or 203 in the same layer having a closed-loop structure.

In particular, the metal interconnect 203a forms a loop-shaped pad periphery metal interconnect so as to surround the periphery of the subpad region. It can be said that, corresponding to this pad periphery metal interconnect, the interconnect layers 104 and 105 shown in FIG. 3 are also provided with a pad periphery metal interconnect like a wide loop so as to surround the subpad region.

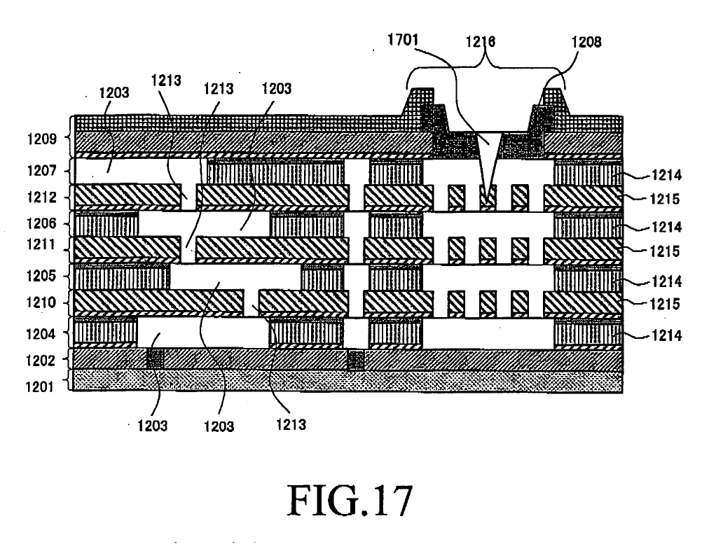

By surrounding the periphery of insulating material portions with metal interconnects like a loop, even if the electrode is damaged or cracked by probing or bonding at an electrode pad as described above with reference to FIG. 17, it is possible to prevent moisture or corrosive gas from intruding into active regions in the chip through this damage or crack. In other words, even if moisture or corrosive gas intrudes into a portion below the bonding pad, it is blocked by the metal interconnects surrounding the portion, and prevented from diffusing laterally from below the bonding pad.

In addition, the moisture or corrosive gas can be prevented from diffusing from the subpad region into the extrapad region by providing the pad periphery metal interconnect. That is, the active portion of the semiconductor device provided in the extrapad region can be reliably protected. As a result, it is possible to provide a semiconductor device resistant to occurrence of failure even if it is made of less strong insulating material having less compact film structure or insulating material prone to peeling off when stacked.

The inventor applied this embodiment to a semiconductor device having multilayer interconnects including copper (Cu) to measure the I-V characteristics of a comb capacitance pattern.

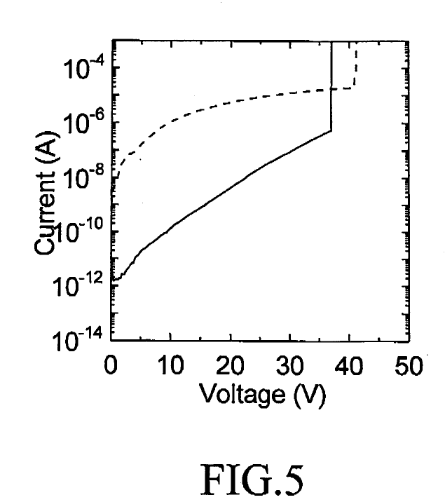

FIG. 5 is a graphical diagram showing the result of this measurement.

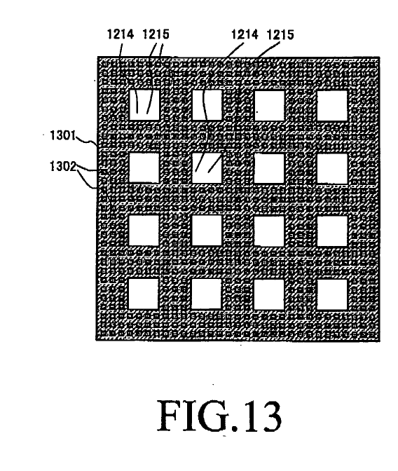

More specifically, here, I-V measurements were performed for the “comb pattern” to which this embodiment is applied, and a “comb pattern” of a comparative example having the structure shown in FIG. 13, respectively. The pattern shape itself for these samples was selected to be identical. In these samples, first, a probe was applied to repeat the I-V measurement three times in a voltage range of 0 to 3 volts so as not to cause breakdown. Three days later, the I-V measurement was performed in a range of 0 to 40 volts. The solid line in FIG. 5 represents the I-V characteristics of the “comb pattern” to which the invention is applied, and the dashed line represents the I-V characteristics of the “comb pattern” of the comparative example.

The sample of the comparative example had a considerable current leak as shown by the dashed line in FIG. 5, which revealed degraded characteristics of the semiconductor device. In addition, the value of the capacitance between interconnects was nearly twice the intrinsic value. This is presumably because the probe caused damage in the I-V measurement initially performed in the range of 0 to 3 volts, and moisture or corrosive gas intruded through the damaged portion to degrade the semiconductor device, as described above with reference to FIG. 17.

In contrast, the sample of the invention did not exhibit any current leak or capacitance degradation as shown by the solid line in FIG. 5, which revealed that the intrinsic characteristics of the “comb pattern” were obtained. That is, it was confirmed that any degradation of the semiconductor device due to damage by the probe was definitely prevented.

In addition, the specific example shown in FIGS. 1 to 4 has a structure such that the planar area occupation ratio of the metal portions constituting the via layer below the electrode pad is smaller than the planar area occupation ratio of the metal portions constituting the interconnect layers below the pad that are provided above and below the via layer. Thus, each layer can be designed so that the ratio of area of the metal portions (data ratio) in the pad portion has a value close to that in the other portion. In this way, when embedded Cu interconnects are formed using CMP method, occurrence of recess called “erosion” or “dishing” can be suppressed to make the interconnect height uniform. As a result, problems such as peeling off and leaks between interconnects can be avoided.

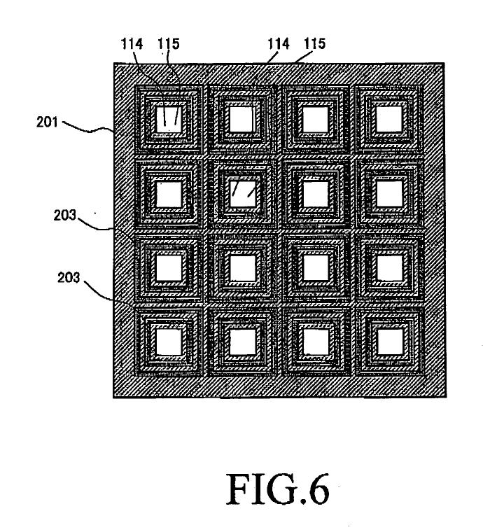

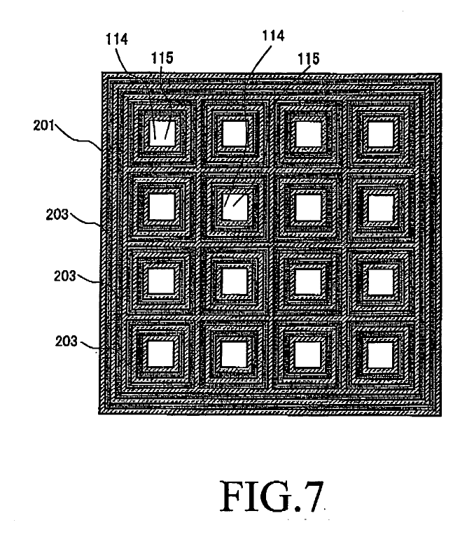

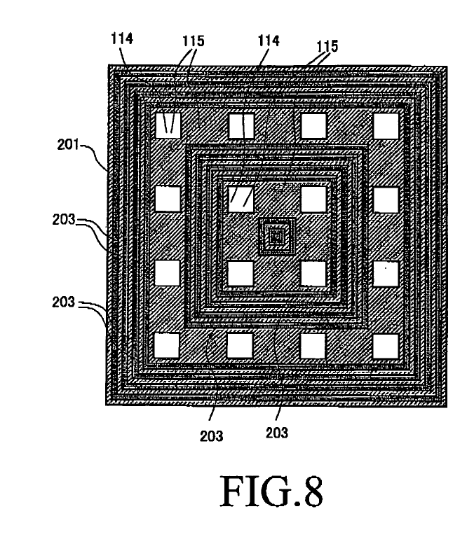

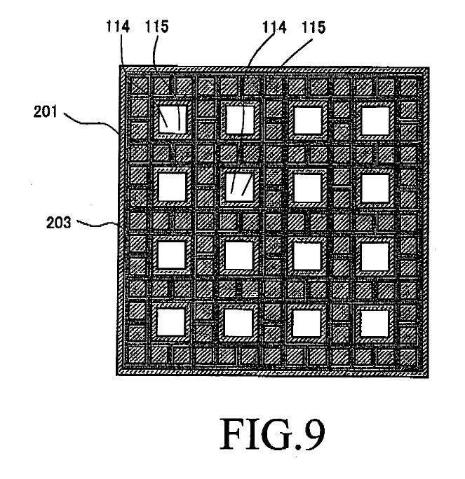

FIGS. 6 to 9 are plan views showing variations of this embodiment. More specifically, these figures are perspective plan views showing the adjacent via layer and interconnect layer superimposed from the upper surface only in the subpad portion, and show the arrangement relationship among the low-k insulating film 114 in the interconnect layer, the low-k insulating film 115 in the via layer, the metal portion 201 in the interconnect layer, and the metal portion 203 in the via layer.

In any of these variations, both the via layer and the interconnect layer include both of the metal interconnect 201 (or 203) and low-k insulating material 114 (or 115). Among the insulating materials in various layers below the pad, the portion 114 (or 115) adjacent to the insulating material portion of the overlying and underlying layers is always surrounded by the metal interconnect 201 (or 203) having a closed-loop structure in the same layer, except for the periphery portion below the pad. As a result, these variations have effects similar to those described above with reference to FIGS. 1 to 4.

### Second Embodiment

Next, the second embodiment of the invention will be described.

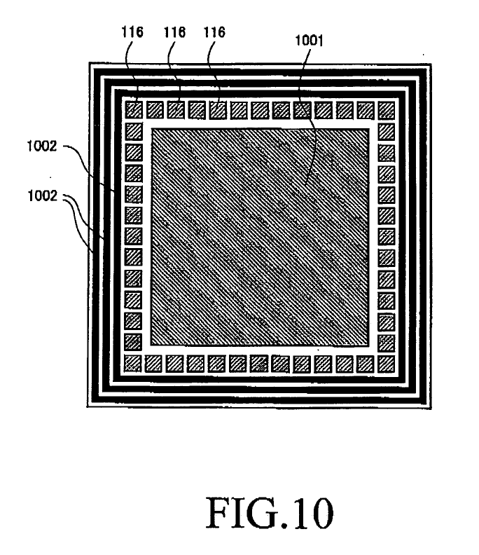

FIG. 10 is a perspective plan view illustrating the planar structure of a relevant part of a semiconductor device according to this embodiment.

More specifically, in this specific example, a plurality of bonding pads are located around the chip. A plurality of loop-shaped chip periphery metal interconnects 1002 are located along the periphery of the chip so as to surround the inside 1001 of the chip including subpad regions 116 underlying these bonding pads. The chip periphery metal interconnect 1002 is provided for all the layers including low-k insulating material.

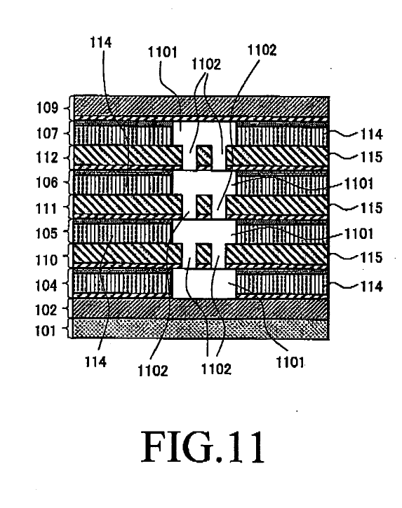

FIG. 11 is a schematic view showing a cross-sectional structure of each chip periphery metal interconnect 1002.

The interconnect layers 104, 105, 106, and 107 are provided with interconnects 1101, respectively. The via layers 110, 111, and 112 are provided with interconnect layers 1102, respectively. In addition, each of the interconnect layers 104, 105, 106, and 107 is provided with insulating film 114 made of low-k material. Each of the via layers 110, 111, and 112 is also provided with insulating film 115 made of low-k material.

The metal interconnects 1101 provided in the interconnect layers 104, 105, 106, and 107 and the metal interconnects 1102 provided in the via layers 110, 111, and 112 have contact with adjacent counterparts between the layers to form a continuous metal shielding wall.

A wafer in which semiconductor chips having the above-described structure are formed vertically and horizontally is diced into individual semiconductor chips. The chip is mounted on a packaging substrate or lead frame, and subjected to wire bonding to the electrode pad provided on the subpad region 116 inside the chip periphery metal interconnect 1002 shown in FIG. 10. The structure described above with reference to the first embodiment is adopted for the subpad regions.

According to this embodiment, a plurality of loop-shaped metal interconnects are provided in both the interconnect layers and via layers so as to surround the periphery of the chip. Consequently, it is possible to prevent moisture and corrosive gas from intruding into the chip through low-k material layers (115, 114) exposed to the side surface of the chip. As a result, high reliability can be achieved.

More specifically, when a wafer is diced into chips, the side surface of low-k insulating material is exposed. This may allow intrusion of moisture or corrosive gas through this exposed surface to cause disconnection failure by corroding metal interconnects serving as signal lines or power supply lines in the semiconductor chip. In contrast, according to this embodiment, moisture and corrosive gas are blocked by the metal interconnects (1101, 1102) along the periphery of the chip, and thus no impairment occurs to the function inside the chip. As a result, problems such as current leak and capacitance degradation do not occur. That is, the chip has significantly decreased failures even when it is mounted on a packaging substrate or the like and subjected to wire bonding as with actual end products. This effect is not obtained until the structure below the electrode pad according to the first embodiment is used and the chip configuration according to the second embodiment is implemented.

In particular, when a plurality of chip periphery metal interconnects 1002 are provided, metallic elements that react with moisture or corrosive gas and penetrate into insulating material have limited places to go. Thus the blocking effect is further enhanced. Moreover, as illustrated in FIG. 10, when the interconnect 1102 in the via layer has a smaller width than the interconnects 1101 of the interconnect layers located in the overlying and underlying layers, each layer can be designed so that the ratio of area of the metal portions (data ratio) in the circular portion has a value close to that in the other portion. In this way, when embedded Cu interconnects are formed using CMP method, the interconnect height can be made uniform. As a result, problems such as peeling off and leaks between interconnects can be avoided.

The embodiments of the invention have been described with reference to specific examples. However, the invention is not limited to these specific examples.

For example, in addition to the specific structure and material of each of the elements constituting the semiconductor device such as the front end layer, interconnect layer, via layer, and electrode pad described above, those appropriately modified by those skilled in the art are also encompassed within the scope of the invention, as long as they comprise the feature of the invention.

Any other semiconductor devices that comprise the elements of the invention and can be modified by those skilled in the art are encompassed within the scope of the invention.

1. A semiconductor device comprising:
a semiconductor layer;
a stacked body provided on the semiconductor layer and having a plurality of stacked layers; and
an electrode pad provided on the stacked body, wherein
the stacked body has a subpad region that is located below the electrode pad and an extrapad region that is not located below the electrode pad, and
any portion made of insulating material in the electrode subpad region except a contact plug layer directly above the semiconductor layer in the stacked body is surrounded by a metal interconnect having a closed structure in the same layer.

2. The semiconductor device as claimed in claim 1, wherein each of the plurality of layers includes a pad periphery metal interconnect surrounding the periphery of the subpad region.

3. The semiconductor device as claimed in claim 2, wherein a portion in which the pad periphery metal interconnects provided in respective adjacent layers overlap with each other has a closed structure surrounding the subpad region.

4. The semiconductor device as claimed in claim 2, wherein at least one of the plurality of layers has a plurality of the pad periphery metal interconnects spaced apart by insulating material and formed circularly.

5. The semiconductor device as claimed in claim 2, wherein
the plurality of layers have an interconnect layer provided with an interconnect for electrical connection inside the same layer and a via layer provided with an interconnect for electrical connection between different layers,
the interconnect layer has the pad periphery metal interconnect with a large width, and
the via layer has a plurality of the pad periphery metal interconnects with a small width.

6. The semiconductor device as claimed in claim 1, wherein
the plurality of layers have an interconnect layer provided with an interconnect for electrical connection inside the same layer and a via layer provided with an interconnect for electrical connection between different layers, and
the metal interconnect of the via layer in the subpad region has a smaller planar area than the metal interconnect of the interconnect layer in the subpad region.

7. The semiconductor device as claimed in claim 1, wherein at least one of the plurality of layers has insulating material with lower mechanical strength or hardness than silicon oxide film or FSG (fluorinated silicate glass) as the insulating material.

8. The semiconductor device as claimed in claim 1, wherein at least one of the plurality of layers has insulating material having a relative dielectric constant of 3 or less as the insulating material.

9. The semiconductor device as claimed in claim 1, wherein each of the plurality of layers except the contact plug layer directly above the semiconductor layer has the chip periphery metal interconnect provided in the extrapad region surrounding the vicinity of the periphery of the chip.

10. The semiconductor device as claimed in claim 9, wherein
the plurality of layers have an interconnect layer provided with an interconnect for electrical connection inside the same layer and a via layer provided with an interconnect for electrical connection between different layers,
the interconnect layer has the chip periphery metal interconnect with a large width, and
the via layer has the chip periphery metal interconnect with a small width.

11. The semiconductor device as claimed in claim 9, wherein at least one of the plurality of layers has a plurality of the chip periphery metal interconnects spaced apart by insulating material and formed circularly.

12. A semiconductor device comprising:
a semiconductor layer;
a stacked body provided on the semiconductor layer and having a plurality of stacked layers; and
a plurality of electrode pads provided on the stacked body, wherein
the stacked body has a plurality of subpad regions that are located below the plurality of electrode pads, respectively, and an extrapad region that is not located below the electrode pads, and
each of the plurality of layers includes a chip periphery metal interconnect surrounding all the plurality of subpad regions.

13. The semiconductor device as claimed in claim 12, wherein a portion in which the chip periphery metal interconnects provided in respective adjacent layers overlap with each other has a closed structure surrounding the subpad regions.

14. The semiconductor device as claimed in claim 12, wherein at least one of the plurality of layers has a plurality of the chip periphery metal interconnects spaced apart by insulating material and formed circularly.

15. The semiconductor device as claimed in claim 12, wherein
the plurality of layers have an interconnect layer provided with an interconnect for electrical connection inside the same layer and a via layer provided with an interconnect for electrical connection between different layers,
the interconnect layer has the chip periphery metal interconnect with a large width, and
the via layer has a plurality of the chip periphery metal interconnects with a small width.

16. The semiconductor device as claimed in claim 12, wherein
the plurality of layers have an interconnect layer provided with an interconnect for electrical connection inside the same layer and a via layer provided with an interconnect for electrical connection between different layers, and
the metal interconnect of the via layer in the subpad region has a smaller planar area than the metal interconnect of the interconnect layer in the subpad region.

17. The semiconductor device as claimed in claim 12, wherein at least one of the plurality of layers has insulating material with lower mechanical strength or hardness than silicon oxide-film or fluorinated silicate glass.

18. The semiconductor device as claimed in claim 12, wherein at least one of the plurality of layers has insulating material having a relative dielectric constant of 3 or less.

19. The semiconductor device as claimed in claim 12, wherein each of the plurality of layers includes a plurality of pad periphery metal interconnects surrounding the periphery of the plurality of subpad regions, respectively.

20. The semiconductor device as claimed in claim 19, wherein
the plurality of layers have an interconnect layer provided with an interconnect for electrical connection inside the same layer and a via layer provided with an interconnect for electrical connection between different layers,
the interconnect layer has the pad periphery metal interconnect with a large width, and
the via layer has the pad periphery metal interconnect with a small width.
